(19) United States
(12) Patent Application Publication
(10) Pub. No.: US 2017/0269737 A1
(43) Pub. Date: Sep. 21, 2017

(54) TOUCH SCREEN, MANUFACTURING METHOD THEREOF AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Fuwei ZOU, Beijing (CN); Ming HU, Beijing (CN); Juntao CHEN, Beijing (CN); Taofeng XIE, Beijing (CN); Zhi DU, Beijing (CN); Wenjie SHI, Beijing (CN)

(21) Appl. No.: 15/511,205

(22) PCT Filed: Apr. 8, 2016
(86) PCT No.: PCT/CN2016/078828

§ 371 Date: Mar. 14, 2017

(30) Foreign Application Priority Data
Jun. 10, 2015 (CN) 201510316193.6

(51) Int. Cl. G06F 3/044; H05K 3/42; H05K 3/00; H05K 1/11; H05K 1/02

(52) U.S. Cl. CPC G06F 3/044; H05K 1/115; H05K 1/028; H05K 3/0026; H05K 3/42; G06F 2203/04102; G06F 2203/04103; H05K 2203/107

(57) ABSTRACT

The present disclosure relates to a touch screen, a manufacturing method thereof and a display device. The touch screen comprises: a glass substrate, a touch functional layer on the glass substrate, a white ink frame on the touch functional layer, and a black ink layer partially covering the white ink frame. The black ink layer has an extension portion extending away from the white ink frame along the touch functional layer. The extension portion has a via hole for electrically connecting to the touch functional layer. In this case, by adding a black ink layer on the white ink frame and fabricating a via hole structure in the extension portion of the black ink layer, an electrical connection with the touch functional layer is achieved.

### FIELD

The present disclosure relates to the field of display, and in particular to a touch screen, a manufacturing method thereof and a display device.

### BACKGROUND ART

As an intelligent human-machine interface product, a touch screen has been more and more widely used in many areas of social production and daily life. In particular, it has made the most notable progress in the field of consumer electronics, such as smart phones, tablet computers. There are various kinds of touch screen, mainly including a resistance type, a capacitance type, an infrared type, a surface acoustic wave type and so on. Capacitive touch screens have not only sensitive response, multi-touch support, but also long service life. Therefore, with the maturity of integrated chip control technologies, capacitive touch screens have been the mainstream on the market today.

A new generation of monolithic touch technologies has become the new orientation for development of capacitive touch screens. From a technical perspective, as compared with the conventional double-layered toughened glass touch technologies, a product based on the monolithic touch technologies has a lighter weight, a thinner thickness and a better light transmittance in addition to a simpler structure. A glass substrate and a fitting process can be omitted, which is helpful for reduction of the production cost and improvement of the production yield.

The existing monolithic touch screens mainly have two types of frames: black frames and white frames. Generally, the structure of a typical black-framed monolithic touch screen is formed as follows: firstly fabricating a touch functional layer on a toughened glass and fabricating a black ink frame above the touch functional layer; then fabricating a via hole structure, filling the via hole with black conductive ink and fabricating binding electrodes; and finally connecting a flexible circuit board having an integrated chip to the binding electrodes, thereby forming a monolithic touch screen module. Such a monolithic touch screen structure has advantages such as low cost, excellent performance and high production yield. However, when the black frame is replaced by a white frame, the via hole structure in the module can hardly be achieved for the following reasons: firstly, it is difficult to find white conductive ink matching the white frame (silver paste is not white); secondly, it is difficult to fabricate a via hole by laser etching, because the white ink is not sensitive to laser light; and thirdly, if the via hole is fabricated by a printing process, the production yield of the via hole cannot be ensured. As can be seen, due to the above reasons, it is difficult to fabricate a via hole structure in a touch screen module with a white frame. Therefore, a white frame structure of a touch screen can hardly be achieved.

In view of the above, how to achieve a white frame structure of a touch screen based on the existing touch screen structure is an urgent technical problem to be solved by those skilled in the art.

### SUMMARY

Embodiments of the present disclosure relate to a touch screen, a manufacturing method thereof and a display device, so as to at least eliminate or alleviate the above indicated problems.

An embodiment of the present disclosure provides a touch screen. The touch screen comprises: a glass substrate, a touch functional layer on the glass substrate, a white ink frame on the touch functional layer, and a black ink layer partially covering the white ink frame. The black ink layer has an extension portion extending away from the white ink frame along the touch functional layer. The extension portion has a via hole for electrically connecting to the touch functional layer.

In a possible implementation, in the touch screen provided by an embodiment of the present disclosure, the via hole is filled with black conductive ink.

In a possible implementation, in the touch screen provided by an embodiment of the present disclosure, the extension portion has a length of no greater than 500 μm along the touch functional layer.

In a possible implementation, in the touch screen provided by an embodiment of the present disclosure, the white ink frame has a thickness of 6 μm˜8 μm in a direction perpendicular to the touch functional layer.

In a possible implementation, the touch screen provided by an embodiment of the present disclosure further comprises a flexible circuit board. The flexible circuit board comprises an integrated chip, and the flexible circuit board is electrically connected with the touch functional layer through the via hole.

An embodiment of the present disclosure further provides a method for manufacturing a touch screen, specifically a touch screen as described above. The method for manufacturing a touch screen comprises: forming a touch functional layer on a glass substrate; forming a white ink frame on the glass substrate on which the touch functional layer has been formed; forming a black ink layer on the glass substrate on which the touch functional layer and the white ink frame have been formed, wherein the black ink layer partially covers the white ink frame and has an extension portion extending away from the white ink frame along the touch functional layer; and forming a via hole for electrically connecting to the touch functional layer in the extension portion of the black ink layer.

In a possible implementation, in the method for manufacturing a touch screen provided by an embodiment of the present disclosure, the step of forming a touch functional layer on a glass substrate specifically comprises: forming a touch functional layer on the glass substrate by a patterning process.

In a possible implementation, in the method for manufacturing a touch screen provided by an embodiment of the present disclosure, the step of forming a white ink frame on the glass substrate on which the touch functional layer has been formed specifically comprises: forming a white ink frame by a screen printing process on the glass substrate on which the touch functional layer has been formed.

In a possible implementation, in the method for manufacturing a touch screen provided by an embodiment of the present disclosure, the step of forming a black ink layer on the glass substrate on which the touch functional layer and the white ink frame have been formed specifically comprises: on the glass substrate on which the touch functional layer and the white ink frame have been formed, forming a black ink layer by a screen printing process, wherein the black ink layer partially covers the white ink frame and has an extension portion extending away from the white ink frame along the touch functional layer; and forming by laser etching in the extension portion of the black ink layer a via hole for electrically connecting to the touch functional layer.

In a possible implementation, in the method for manufacturing a touch screen provided by an embodiment of the present disclosure, the via hole formed by laser etching in the extension portion of the black ink layer is in a linear shape. Specifically, the linear shaped via hole has a length of 100 μm˜300 μm and a width of 20 μm˜40 μm.

In a possible implementation, in the method for manufacturing a touch screen provided by an embodiment of the present disclosure, the step of forming a black ink layer on the glass substrate on which the touch functional layer and the white ink frame have been formed specifically comprises: on the glass substrate on which the touch functional layer and the white ink frame have been formed, forming by a screen printing process a black ink layer and a via hole for electrically connecting to the touch functional layer. Specifically, the black ink layer partially covers the white ink frame and has an extension portion extending away from the white ink frame along the touch functional layer. Besides, the via hole is located in the extension portion.

In a possible implementation, in the method for manufacturing a touch screen provided by an embodiment of the present disclosure, the via hole formed by a screen printing process has an aperture of 100 μm˜150 μm.

In a possible implementation, the method for manufacturing a touch screen provided by an embodiment of the present disclosure further comprises: filling the via hole with black conductive ink by a screen printing process.

An embodiment of the present disclosure further provides a display device, comprising a touch screen provided by any of the above embodiments of the present disclosure.

Embodiments of the present disclosure provide a touch screen, a manufacturing method thereof and a display device. The touch screen comprises: a glass substrate, a touch functional layer on the glass substrate, a white ink frame on the touch functional layer, and a black ink layer partially covering the white ink frame. The black ink layer has an extension portion extending away from the white ink frame along the touch functional layer. The extension portion has a via hole for electrically connecting to the touch functional layer. By adding a black ink layer on the white ink frame and fabricating a via hole structure in the extension portion of the black ink layer, electrical connection with the touch functional layer is achieved. Such a touch screen structure not only ensures advantages of a black-framed monolithic touch screen, such as low cost, excellent performance and high production yield, but also avoids difficulties in achieving the via hole structure for a white-framed touch screen. Therefore, the optical density value of the white frame is increased and the apparent representability of the product is improved.

### BRIEF DESCRIPTION OF DRAWINGS

FIG. 1 is a schematic structure view of a touch screen provided by an embodiment of the present disclosure;

FIG. 2 is a schematic structure view of a touch screen provided by another embodiment of the present disclosure; and

FIG. 3 is a flow diagram of a method for manufacturing a touch screen provided by an embodiment of the present disclosure.

### DETAILED DESCRIPTION OF EMBODIMENTS

Specific implementations of the touch screen, the manufacturing method thereof and the display device provided by embodiments of the present disclosure will be explained below in detail with reference to the drawings.

Thicknesses of each film layer as well as sizes and shapes of each region in the drawings are not provided to reflect the true scale of each component in the touch screen, but only for the purpose of illustrating contents of the present disclosure.

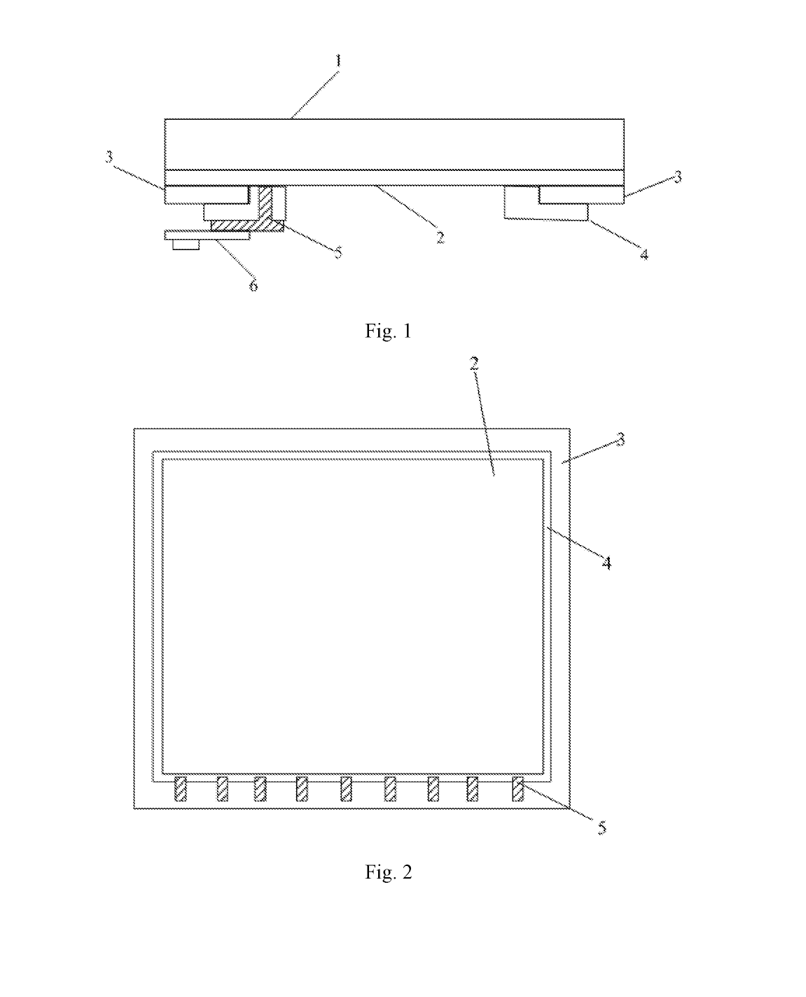

An embodiment of the present disclosure provides a touch screen. As shown in FIGS. 1 and 2, the touch screen may comprise: a glass substrate 1, a touch functional layer 2 on the glass substrate 1, a white ink frame 3 on the touch functional layer 2, and a black ink layer 4 partially covering the white ink frame 3. The black ink layer 4 may have an extension portion which can extend away from the white ink frame 3 along the touch functional layer 2. Furthermore, the extension portion may also have a via hole 5 for electrically connecting to the touch functional layer 2.

The touch screen provided by an embodiments of the present disclosure may specifically comprise: a glass substrate 1, a touch functional layer 2 on the glass substrate 1, a white ink frame 3 on the touch functional layer 2, and a black ink layer 4 partially covering the white ink frame 3. Besides, the black ink layer 4 could have an extension portion extending away from the white ink frame 3 along the touch functional layer 2, and the extension portion may also have a via hole 5 for electrically connecting to the touch functional layer 2. In this way, by adding a black ink layer on the white ink frame and fabricating a via hole structure in the extension portion of the black ink layer, electrical connection with the touch functional layer will be achieved. Such a touch screen structure not only ensures advantages of a black-framed monolithic touch screen, such as low cost, excellent performance and high production yield, but also avoids difficulties in achieving the via hole structure for a white-framed touch screen. Therefore, the optical density value of the white frame is increased and the apparent representability of the product is improved.

According to specific implementations, in the touch screen provided by an embodiment of the present disclosure, the via hole may be filled with black conductive ink. Specifically, in the touch screen provided by an embodiments of the present disclosure, the via hole fabricated in the extension portion of the black ink layer can be filled with black conductive ink, and binding electrodes are also fabricated, in order to achieve electrical connection between the via hole in the touch screen structure and the touch functional layer. In this case, the flexible circuit board will be connected to the binding electrodes, and thereby electrical connection with the touch functional layer is achieved further by means of the via hole. Finally, a touch screen module is formed and a touch function of the touch screen is realized.

According to specific implementations, in the touch screen provided by an embodiment of the present disclosure, the extension portion may have a length of no greater than 500 μm along the touch functional layer. Specifically, a black ink layer is added on a white ink frame, in order to achieve a white-framed touch screen structure. Besides, the black ink layer may also have an extension portion extending away from the white ink frame along the touch functional layer. The extension portion is used for fabricating a via hole structure. In addition, the extension portion may have a length of no greater than 500 μm along the touch functional layer, thereby avoiding influences on the aperture ratio of the display region. According to specific implementations, in the touch screen provided by an embodiments of the present disclosure, the white ink frame may have a thickness of 6 μm˜8 μm in a direction perpendicular to the touch functional layer. Specifically, in the touch screen provided by an embodiment of the present disclosure, a white ink frame is arranged on the touch functional layer, in order to achieve a white frame structure for the touch screen. Furthermore, in order to achieve electrical connection with the touch functional layer, a via hole structure can be arranged in the frame region of the touch screen structure. Furthermore, in order to obtain the via hole structure of the white-ink-framed touch screen, a black ink layer can be arranged on the white ink frame, and the black ink layer could also an extension portion extending away from the white ink frame along the touch functional layer. In this case, a via hole structure can be arranged in the extension portion. Either a laser etching process or a screen printing process can be adopted for accomplishing the via hole fabrication in the extension portion. In order to better implement the via hole fabrication, the frame structure cannot be too thick. Therefore, a thickness of the white ink frame could be arranged to be 6 μm˜8 μm, so as to facilitate implementations of the via hole fabrication.

According to specific implementations, as shown in FIG. 1, the touch screen provided by an embodiment of the present disclosure can further comprise a flexible circuit board 6. Specifically, the flexible circuit board 6 may comprise an integrated chip. Besides, the flexible circuit board 6 can also be electrically connected with the touch functional layer 2 through a via hole 5. To be specific, in the touch screen provided by an embodiment of the present disclosure, for the purpose of obtaining a touch function of the touch screen, the flexible circuit board 6 with the integrated chip can be electrically connected with the touch functional layer 2, thus forming a complete touch module and realizing a touch function thereof. In this case, the via hole structure can be filled with black conductive ink and binding electrodes could be fabricated therein. Specifically, the flexible circuit board 6 with the integrated chip can be connected with the binding electrodes, and thereby electrically connected with the touch functional layer.

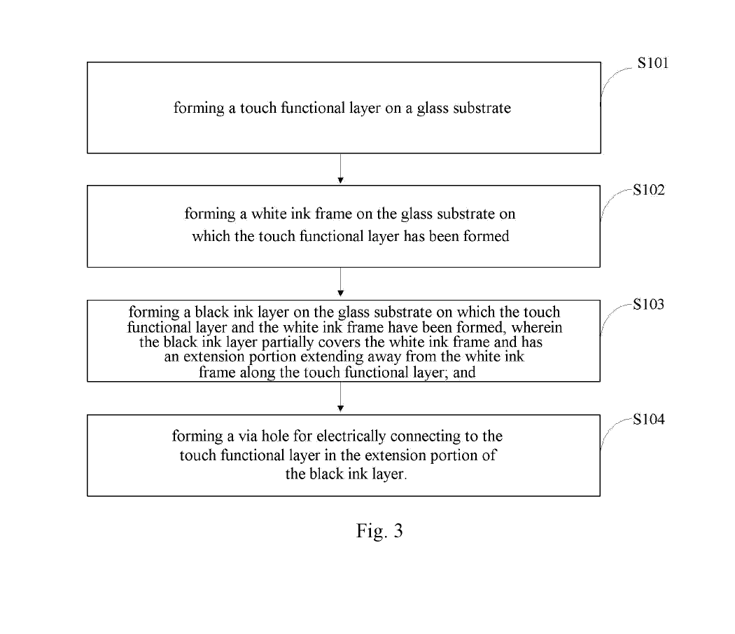

Based on a same inventive concept, an embodiment of the present disclosure also provides a method for manufacturing a touch screen. As shown in FIG. 3, the method can comprise the following steps.

S101, forming a touch functional layer on a glass substrate;

S102, forming a white ink frame on the glass substrate on which the touch functional layer has been formed;

S103, forming a black ink layer on the glass substrate on which the touch functional layer and the white ink frame have been formed, wherein the black ink layer partially covers the white ink frame and has an extension portion extending away from the white ink frame along the touch functional layer; and

S104, forming a via hole for electrically connecting to the touch functional layer in the extension portion of the black ink layer.

Specifically, in the method for manufacturing a touch screen provided by an embodiment of the present disclosure, a touch functional layer is formed on a toughened glass substrate by a patterning process. The film layer structure of the touch functional layer can be a transparent conductive thin film structure, for example, an ITO layer, a silver nanowire structure, a metal grid structure, or a graphene film layer. Besides, the pattern structure of the touch functional layer can be a single-faced multi-touch structure. A white ink frame can be formed on the touch functional layer, and then a black ink layer could be formed on the white ink frame. Specifically, the black ink layer partially covers the white ink frame and has an extension portion extending away from the white ink frame along the touch functional layer. In this way, a via hole structure can be achieved in the extension portion of the black ink layer. That is to say, a via hole structure is achieved on the basis of a white ink frame structure. Therefore, difficulties in obtaining a via hole structure for a white-framed touch screen will be solved. Meanwhile, the optical density value of the white frame can be increased and the apparent representability of the product will be improved.

According to specific implementations, in the method for manufacturing a touch screen provided by an embodiment of the present disclosure, step S102 can specifically comprise: forming a white ink frame by a screen printing process on the glass substrate on which the touch functional layer has been formed. Specifically, in the method for manufacturing a touch screen provided by an embodiment of the present disclosure, a white ink frame can be formed on the touch functional layer by a screen printing process. Generally, a film thickness of the white ink frame can be controlled in the range of 6 μm˜8 μm, which facilitates the fabrication of a via hole structure. Thereby, the flexible circuit board with an integrated chip can be electrically connected with the touch functional layer through a via hole, and a touch module structure will be finally achieved.

According to specific implementations, in the method for manufacturing a touch screen provided by an embodiment of the present disclosure, step S103 and step S104 can specifically comprise: on the glass substrate on which the touch functional layer and the white ink frame have been formed, forming a black ink layer by a screen printing process, wherein the black ink layer partially covers the white ink frame and has an extension portion extending away from the white ink frame along the touch functional layer; and forming by laser etching in the extension portion of the black ink layer a via hole for electrically connecting to the touch functional layer. Specifically, in the method for manufacturing a touch screen provided by an embodiment of the present disclosure, a black ink layer can be fabricated by a screen printing process on the glass substrate on which the touch functional layer and the white ink frame have been formed, such that the black ink layer partially covers the white ink frame and has an extension portion extending away from the white ink frame along the touch functional layer. After that, a via hole structure can be obtained in the extension portion of the black ink layer by a laser etching process. In this way, a via hole structure for a white-framed touch screen can be achieved, and accordingly, difficulties in achieving a via hole structure for a white-framed touch screen will be solved. Meanwhile, the optical density value of the white frame is increased and the apparent representability of the product is improved.

According to specific implementations, in the method for manufacturing a touch screen provided by an embodiment of the present disclosure, the via hole formed by laser etching in the extension portion of the black ink layer could be in a linear shape. Optionally, the linear shaped via hole may have a length of 100 μm˜300 μm and a width of 20 μm˜40 μm. Specifically, in the method for manufacturing a touch screen provided by an embodiment of the present disclosure, the via hole structure can be formed by laser etching in the extension portion of the black ink layer. The via hole formed in this way could be in a linear shape too. Preferably, the linear shaped via hole here may also have a length of 100 μm˜300 μm and a width of 20 μm˜40 μm. Binding electrodes can be also fabricated in the via hole structure. In this case, the flexible circuit board can be connected to the binding electrodes. Thereby, electrical connection with the touch to functional layer is achieved by means of the via hole structure, and a touch function of the touch screen is finally realized.

According to specific implementations, in the method for manufacturing a touch screen provided by an embodiment of the present disclosure, step S103 and step S104 can specifically comprise: on the glass substrate on which the touch functional layer and the white ink frame have been formed, forming by a screen printing process a black ink layer and a via hole for electrically connecting to the touch functional layer. Optionally, the black ink layer could partially cover the white ink frame and has an extension portion extending away from the white ink frame along the touch functional layer. Besides, the via hole can be located in the extension portion. Specifically, in the method for manufacturing a touch screen provided by an embodiment of the present disclosure, the black ink layer and the via hole structure can be formed simultaneously by a screen printing process. In this way, the black ink layer and the via hole structure can be formed by a single patterning process, which is helpful for simplifying the manufacturing process of the touch screen and reducing its relevant production cost.

According to specific implementations, in the method for manufacturing a touch screen provided by an embodiment of the present disclosure, the via hole formed by a screen printing process could have an aperture of 100 μm˜150 μm. Specifically, in the method for manufacturing a touch screen provided by an embodiment of the present disclosure, the black ink layer and the via hole structure can be formed simultaneously by a screen printing process. The via hole formed in this way generally has an aperture of 100 μm˜150 μm. Binding electrodes could also be fabricated in the via hole structure, and in turn the flexible circuit board can be connected to the binding electrodes. Thereby, electrical connection with the touch functional layer will be achieved by means of a via hole filled with black conductive ink, and the touch function of the touch screen will be finally realized.

Based on a same inventive concept, an embodiment of the present disclosure further provides a display device. The display device can comprise a touch screen provided by any of the above embodiments of the present disclosure. The display device can be applied to any product or component having a display function, such as a handset, a tablet computer, a television, a display, a notebook computer, a digital photo frame, a navigator and the like. Since the principle of the display device is similar to that of the touch screen, for implementations of the display device, implementations of the touch screen can be referred to, which will not be repeated for simplicity.

Embodiments of the present disclosure provide a touch screen, a manufacturing method thereof and a display device. The touch screen comprises: a glass substrate, a touch functional layer on the glass substrate, a white ink frame on the touch functional layer, and a black ink layer partially covering the white ink frame. The black ink layer has an extension portion extending away from the white ink frame along the touch functional layer. The extension portion has a via hole for electrically connecting to the touch functional layer. In this way, by adding a black ink layer on the white ink frame and fabricating a via hole structure in the extension portion of the black ink layer, electrical connection with the touch functional layer is achieved. Such a touch screen structure not only ensures advantages of a black-framed monolithic touch screen, such as low cost, excellent performance and high production yield, but also avoids difficulties in achieving the via hole structure for a white-framed touch screen. Therefore, the optical density value of the white frame is increased and the apparent representability of the product is improved.

Obviously, those skilled in the art can make various modifications and variations to the present disclosure without deviating from spirits and scopes of the present disclosure. Thus if these modifications and variations to the present disclosure fall within the scopes of the claims of the present disclosure and the equivalent techniques thereof, the present disclosure is intended to include them too.

1. A touch screen, comprising:
a glass substrate,
a touch functional layer on the glass substrate,
a white ink frame on the touch functional layer, and
a black ink layer partially covering the white ink frame; wherein
the black ink layer has an extension portion extending away from the white ink frame along the touch functional layer, and
the extension portion has a via hole for electrically connecting to the touch functional layer.

2. The touch screen according to claim 1, wherein the via hole is filled with black conductive ink.

3. The touch screen according to claim 2, wherein the extension portion has a length of no greater than 500 μm along the touch functional layer.

4. The touch screen according to claim 3, wherein the white ink frame has a thickness of 6 μm˜8 μm in a direction perpendicular to the touch functional layer.

5. The touch screen according to claim 1, further comprising:
a flexible circuit board; wherein
the flexible circuit board comprises an integrated chip, and
the flexible circuit board is electrically connected with the touch functional layer through the via hole.

6. A method for manufacturing the touch screen according to claim 1, comprising:
forming a touch functional layer on a glass substrate;
forming a white ink frame on the glass substrate on which the touch functional layer has been formed;
forming a black ink layer on the glass substrate on which the touch functional layer and the white ink frame have been formed, wherein the black ink layer partially covers the white ink frame and has an extension portion extending away from the white ink frame along the touch functional layer; and
forming a via hole for electrically connecting to the touch functional layer in the extension portion of the black ink layer.

7. The method according to claim 6, wherein the step of forming a touch functional layer on a glass substrate comprises:
forming a touch functional layer on the glass substrate by a patterning process.

8. The method according to claim 6, wherein the step of forming a white ink frame on the glass substrate on which the touch functional layer has been formed comprises:
forming a white ink frame by a screen printing process on the glass substrate on which the touch functional layer has been formed.

9. The method according to claim 6, wherein the step of forming a black ink layer on the glass substrate on which the touch functional layer and the white ink frame have been formed comprises:
on the glass substrate on which the touch functional layer and the white ink frame have been formed, forming a black ink layer by a screen printing process, wherein the black ink layer partially covers the white ink frame and has an extension portion extending away from the white ink frame along the touch functional layer; and
forming by laser etching in the extension portion of the black ink layer a via hole for electrically connecting to the touch functional layer.

10. The method according to claim 9, wherein
the via hole formed by laser etching in the extension portion of the black ink layer is in a linear shape, and
the linear shaped via hole has a length of 100 μm˜300 μm and a width of 20 μm˜40 μm.

11. The method according to claim 6, wherein the step of forming a black ink layer on the glass substrate on which the touch functional layer and the white ink frame have been formed comprises:
on the glass substrate on which the touch functional layer and the white ink frame have been formed, forming by a screen printing process a black ink layer and a via hole for electrically connecting to the touch functional layer; wherein
the black ink layer partially covers the white ink frame and has an extension portion extending away from the white ink frame along the touch functional layer, and
the via hole is located in the extension portion.

12. The method according to claim 11, wherein the via hole formed by a screen printing process has an aperture of 100 μm˜150 μm.

13. The method according to claim 6, further comprising:
filling the via hole with black conductive ink by a screen printing process.

14. A display device comprising the touch screen according to claim 1.

15. The method according to claim 7, further comprising:
filling the via hole with black conductive ink by a screen printing process.

16. The method according to claim 8, further comprising:
filling the via hole with black conductive ink by a screen printing process.

17. The method according to claim 9, further comprising:
filling the via hole with black conductive ink by a screen printing process.

18. The method according to claim 11, further comprising:
filling the via hole with black conductive ink by a screen printing process.

19. The display device according to claim 14, wherein the via hole is filled with black conductive ink.

20. The display device according to claim 14, wherein the touch screen further comprises:
a flexible circuit board; wherein
the flexible circuit board comprises an integrated chip, and
the flexible circuit board is electrically connected with the touch functional layer through the via hole.
